(19) United States
(12) Patent Application Publication
(10) Pub. No.: US 2024/0116751 A1
(43) Pub. Date: Apr. 11, 2024

(54) CHIP PACKAGE AND MANUFACTURING METHOD THEREOF

(71) Applicant: Xintec Inc., Taoyuan City (TW)

(72) Inventors: Chia-Ming CHENG, New Taipei City (TW); Shu-Ming CHANG, New Taipei City (TW); Tsang Yu LIU, Zhubei City (TW)

(21) Appl. No.: 18/480,385

(22) Filed: Oct. 3, 2023

Related U.S. Application Data
(60) Provisional application No. 63/413,513, filed on Oct. 5, 2022.

(51) Int. Cl. B81B 7/00; B81C 1/00

(52) U.S. Cl. CPC B81B 7/0064; B81B 7/007; B81C 1/00269; B81C 2203/0118

(57) ABSTRACT

A chip package includes an application chip, a micro-electromechanical systems (MEMS) chip, a conductive element, a bonding wire, and a molding compound. The application chip has a conductive pad. The MEMS chip is located on the application chip, and includes a main body and a cap. The main body is located between the cap and the application chip. The main body has a conductive pad. The conductive element is located on the conductive pad of the main body of the MEMS chip. The bonding wire extends from the conductive element to the conductive pad of the application chip. The molding compound is located on the application chip and surrounds the MEMS chip. The conductive element and the bonding wire are located in the molding compound.

### CROSS-REFERENCE TO RELATED APPLICATIONS

This application claims priority to U.S. Provisional Application Ser. No. 63/413,513, filed Oct. 5, 2022 which is herein incorporated by reference.

### BACKGROUND

### Field of Invention

The present disclosure relates to a chip package and a manufacturing method of the chip package.

### Description of Related Art

Generally speaking, a chip package with multiple functions can have stacked chips, such as micro-electromechanical systems (MEMS) chips and application specific integrated circuit (ASIC) chips. The electrical connection between different chips, the grounding of the MEMS and the shielding of the MEMS are not easy. In addition, it is also difficult to balance the miniaturization design and structural strengthening of the chip package with multiple functions.

### SUMMARY

One aspect of the present disclosure provides a chip package.

According to some embodiments of the present disclosure, a chip package includes an application chip, a micro-electromechanical systems (MEMS) chip, a conductive element, a bonding wire, and a molding compound. The application chip has a conductive pad. The MEMS chip is located on the application chip, and includes a main body and a cap. The main body is located between the cap and the application chip. The main body has a conductive pad. The conductive element is located on the conductive pad of the main body of the MEMS chip. The bonding wire extends from the conductive element to the conductive pad of the application chip. The molding compound is located on the application chip and surrounds the MEMS chip. The conductive element and the bonding wire are located in the molding compound.

In some embodiments, the molding compound is in direct contact with the conductive element and the bonding wire.

In some embodiments, a top surface of the molding compound is higher than the highest position of the bonding wire.

In some embodiments, the application chip has a through hole, and the chip package further includes a redistribution layer and a conductive structure. The redistribution layer is electrically connected to another conductive pad of the application chip by the through hole, and extends to a surface of the application chip facing away from the MEMS chip. The conductive structure is located on the redistribution layer.

One aspect of the present disclosure provides a manufacturing method of a chip package.

According to some embodiments of the present disclosure, a manufacturing method of a chip package includes cutting a cap of a micro-electromechanical systems (MEMS) wafer to form a plurality of scribe lines; cutting a main body of the MEMS wafer along the scribe lines to form at least one MEMS chip, wherein the MEMS chip includes the cap and the main body that are diced; disposing the MEMS chip on an application wafer; bonding a conductive element on a conductive pad of the main body of the MEMS chip; extending a bonding wire from the conductive element to a conductive pad of the application wafer; and forming a molding compound on the application wafer to enable the molding compound surrounding the MEMS chip, wherein the conductive element and the bonding wire are located in the molding compound.

In some embodiments, the manufacturing method of the chip package further includes forming a through hole in the application wafer; forming a redistribution layer that is electrically connected to another conductive pad of the application wafer by the through hole, and extends to a surface of the application wafer facing away from the MEMS chip; and forming a conductive structure on the redistribution layer.

One aspect of the present disclosure provides a chip package.

According to some embodiments of the present disclosure, a chip package includes an application chip, a micro-electromechanical systems (MEMS) chip, a first conductive element, and a molding compound. The MEMS chip is located on the application chip, and includes a MEMS structure and a cap covering the MEMS structure. The MEMS structure is located between the cap and the application chip, and a surface of the cap facing away from the application chip has a metal layer. The first conductive element is located on the conductive pad of the application chip. The molding compound is located on the application chip, covers the metal layer, and surrounds the MEMS chip. The first conductive element is located in the molding compound.

In some embodiments, the molding compound has a through hole aligned with the first conductive element, and the chip package further includes a redistribution layer. A first section of the redistribution layer is electrically connected to the first conductive element in the molding compound, and extends to a surface of the molding compound facing away from the MEMS chip.

In some embodiments, a second section of the redistribution layer is electrically connected to the metal layer and extends to said surface of the molding compound.

In some embodiments, the chip package further includes a conductive structure located on the second section of the redistribution layer.

In some embodiments, the chip package further includes a conductive structure located on the first section of the redistribution layer.

In some embodiments, said surface of the cap has an isolation layer between the metal layer and said surface of the cap.

In some embodiments, the chip package further includes a bonding wire extending from the first conductive element to the metal layer.

In some embodiments, the chip package further includes a second conductive element located on the metal layer and in the molding compound.

In some embodiments, the chip package further includes a redistribution layer located on a surface of the molding compound facing away from the MEMS chip, and electrically connected to the second conductive element.

In some embodiments, the chip package further includes a conductive structure located on the redistribution layer.

One aspect of the present disclosure provides a manufacturing method of a chip package.

According to some embodiments of the present disclosure, a manufacturing method of a chip package includes bonding a micro-electromechanical systems (MEMS) wafer on an application wafer, wherein the MEMS wafer includes a MEMS structure and a cap covering the MEMS structure, wherein the MEMS structure is located between the cap and the application wafer; forming a metal layer on a surface of the cap facing away from the application wafer; cutting the MEMS wafer to form at least one MEMS chip such that a conductive pad of the application wafer is exposed; bonding a first conductive element on the conductive pad of the application wafer; and forming a molding compound on the application wafer to cover the metal layer and surround the MEMS chip, wherein the first conductive element is located in the molding compound.

In some embodiments, the manufacturing method of the chip package further includes forming a through hole and an opening in the molding compound by a laser, such that the first conductive element is exposed through the through hole, and the metal layer is exposed through the opening; and forming a redistribution layer such that a first section and a second section of the redistribution layer are electrically connected to the first conductive element in the through hole and the metal layer in the opening, respectively, wherein the first section and the second section of the redistribution layer extend to a surface of the molding compound facing away from the MEMS chip.

In some embodiments, the manufacturing method of the chip package further includes before forming the metal layer, forming an isolation layer on said surface of the cap.

In some embodiments, the manufacturing method of the chip package further includes bonding a second conductive element on the metal layer, such that the second conductive element is located in the molding compound after forming the molding compound; forming a bonding wire that extends from the first conductive element to the metal layer; and forming a redistribution layer on a surface of the molding compound facing away from the MEMS chip, such that the redistribution layer is electrically connected to the second conductive element.

In the aforementioned embodiments of the present disclosure, since the chip package has the conductive element in the molding compound, an electrical connection between the application chip and the MEMS chip and/or an electrical connection between the application chip and the conductive structure on the molding compound can be achieved. The chip package and the manufacturing method thereof can not only realize the integration of chips with different functions, but also effectively solve the problem of electrical connection between different chips and the problem of the grounding and shielding of micro-electromechanical systems, and can also achieve a balance between miniaturization design and structural strengthening.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a chip package according to one embodiment of the present disclosure.

FIGS. 2 to 9 are perspective views at intermediate stages of a manufacturing method of the chip package of FIG. 1.

FIG. 10 is a cross-sectional view of a chip package according to another embodiment of the present disclosure.

FIGS. 11 to 15 are cross-sectional views at intermediate stages of a manufacturing method of the chip package of FIG. 10.

FIG. 16 is a cross-sectional view of a chip package according to still another embodiment of the present disclosure.

FIGS. 17 to 21 are cross-sectional views at intermediate stages of a manufacturing method of the chip package of FIG. 16.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

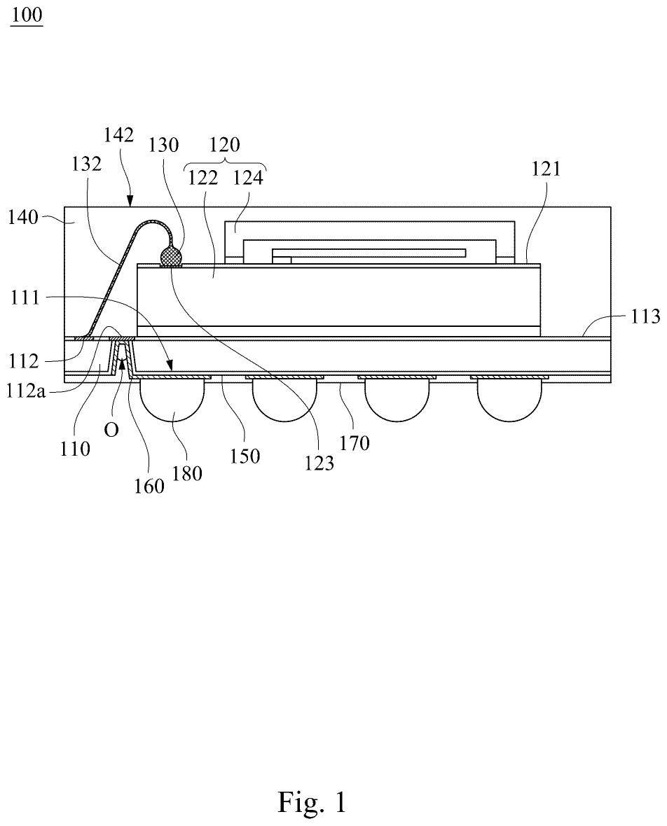

FIG. 1 is a cross-sectional view of a chip package 100 according to one embodiment of the present disclosure. As shown in FIG. 1, the chip package 100 includes an application chip 110, a micro-electromechanical systems (MEMS) chip 120, a conductive element 130, a bonding wire 132, and a molding compound 140. The application chip 110 may be an application specific integrated circuit (ASIC) chip. The application chip 110 has a conductive pad 112. The MEMS chip 120 is located on the application chip 110. The MEMS chip 120 includes a main body 122 and a cap 124, and the main body 122 is located between the cap 124 and the application chip 110. The main body 122 of the MEMS chip 120 has a conductive pad 123. The conductive element 130 is located on the conductive pad 123 of the main body 122 of the MEMS chip 120. The bonding wire 132 extends from the conductive element 130 to the conductive pad 112 of the application chip 110, such that the MEMS chip 120 can be electrically connected to the application chip 110. The molding compound 140 is located on the application chip 110 and surrounds the MEMS chip 120. The conductive element 130 and the bonding wire 132 are located in the molding compound 140.

In some embodiments, the material of the conductive element 130 may be gold, and the shape may be spherical or cylindrical. The bonding wire 132 and the conductive element 130 may be the same material, such as gold. The MEMS chip 120 can be applied to gyroscope or accelerometer, but the present disclosure is not limited in this regard. The main body 122 of the MEMS chip 120 may include an isolation layer 121, and the top surface of the conductive pad 123 is exposed by the isolation layer 121 for bonding the conductive element 130. Furthermore, the application chip 110 may include an isolation layer 113, and the top surface of the conductive pad 112 is exposed by the isolation layer 113 for bonding the bonding wire 132.

Specifically, since the chip package 100 has the conductive element 130 in the molding compound 140, the electrical connection between the application chip 110 and the MEMS chip 120 can be achieved. The chip package 100 can not only realize the integration of chips with different functions, but also effectively solve the problem of electrical connections between different chips, and can also achieve a balance between miniaturization design and structural strengthening.

In this embodiment, the molding compound 140 can be in direct contact with the conductive element 130 and the bonding wire 132, and has the advantages of positioning, isolation, and protection. In addition, a surface 142 (i.e., a top surface) of the molding compound 140 is higher than the highest position of the bonding wire 132, and thus the entire bonding wire 132 can be embedded in the molding compound 140, which is helpful for planarization design.

Moreover, the application chip 110 may further have a through hole O. The chip package 100 further includes an isolation layer 150, a redistribution layer 160, a passivation layer 170, and a conductive structure 180. The isolation layer 150 is located on a surface 111 of the application chip 110 facing away from the MEMS chip 120, and is located on the sidewall of the through hole O. The through hole O is aligned with another conductive pad 112a. The bottom surface of the conductive pad 112a is exposed by the through hole O and the isolation layer 150. The redistribution layer 160 is electrically connected to the conductive pad 112a of the application chip 110 by the through hole O, and extends to the surface 111 of the application chip 110. The redistribution layer 160 is located on the bottom surface of the isolation layer 150. The passivation layer 170 is located on the surface 111 of the application chip 110 and covers the redistribution layer 160 and the isolation layer 150. The conductive structure 180 is located on the redistribution layer 160 and protrudes outward from the passivation layer 170, and can be electrically connected to an external device (e.g., a printed circuit board).

It is to be noted that the connection relationships, the materials, and the advantages of the elements described above will not be repeated in the following description. In the following description, the manufacturing method of the chip package 100 will be explained.

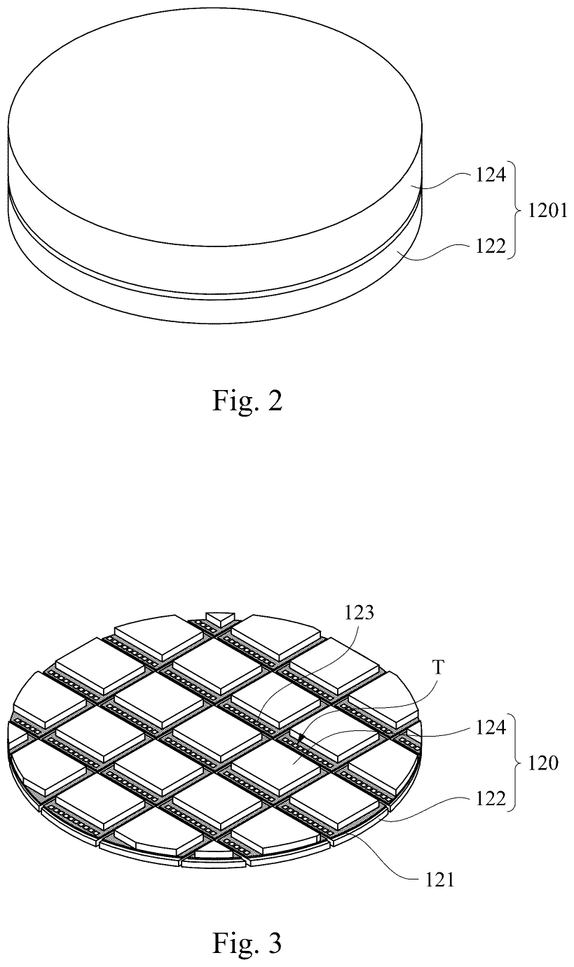

FIGS. 2 to 9 are perspective views at intermediate stages of a manufacturing method of the chip package of FIG. 1. As shown in FIG. 2 and FIG. 3, a MEMS wafer 1201 is provided. The term “wafer” in the description is referred to as a semiconductor structure which is not yet cut to form plural chips. A grinding treatment may be performed on the cap 124 and the main body 122 at two opposite sides of the MEMS wafer 1201. Thereafter, the cap 124 of the MEMS wafer 1201 is cut to form a plurality of scribe lines T. The scribe line T can expose the conductive pad 123 of the main body 122. Afterwards, the main body 122 of the MEMS wafer 1201 along the scribe lines T can be cut to form at least one MEMS chip 120, wherein the MEMS chip 120 includes the diced cap 124 and the diced main body 122.

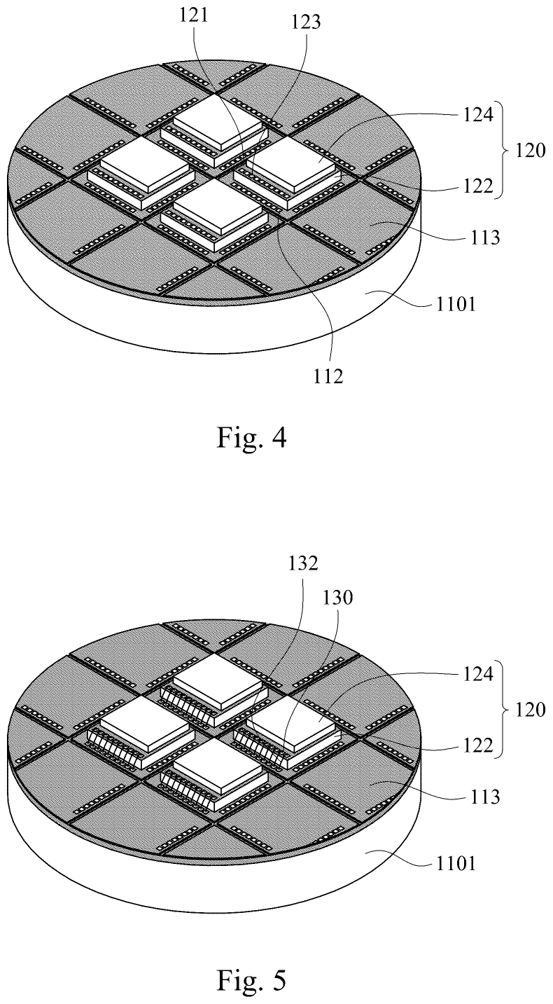

As shown in FIG. 4 and FIG. 5, after the formation of the MEMS chip 120, the MEMS chip 120 can be disposed on an application wafer 1101 through an attaching process. The conductive pad 112 of the application wafer 1101 is exposed from the isolation layer 113. Thereafter, the conductive element 130 may be bonded on the conductive pad 123 of the main body 122 of the MEMS chip 120, and the bonding wire 132 is extended from the conductive element 130, and thus the bonding wire 132 extends to the conductive pad 112 of the application wafer 1101.

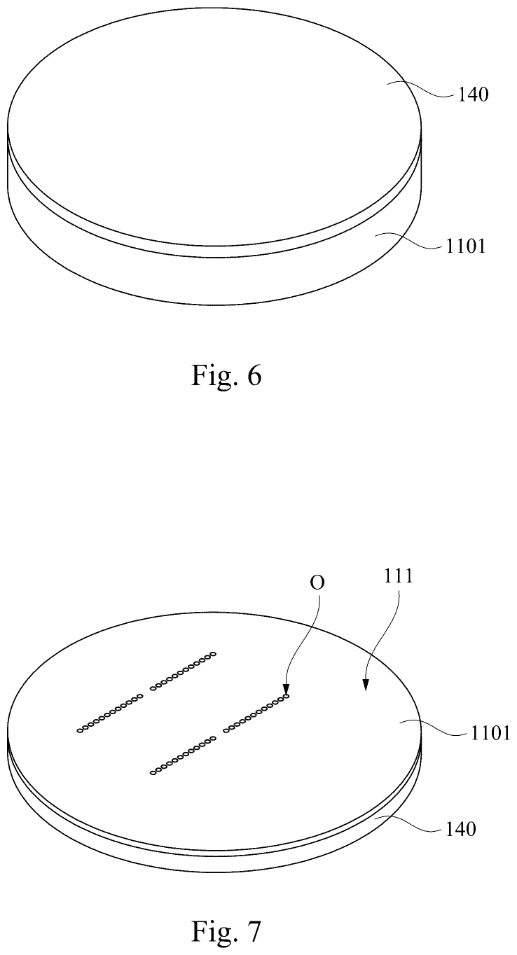

As shown in FIG. 6 and FIG. 7, after the formation of the bonding wire 132, the molding compound 140 may be formed on the application wafer 1101, such that the molding compound 140 surrounds the MEMS chip 120, and the conductive element 130 and the bonding wire 132 are located in the molding compound 140. Thereafter, a grinding treatment can be performed on the molding compound 140. For example, the molding compound 140 is thinned from 450 μm to 390 μm, but the present disclosure is not limited in this regard. Next, the structure of FIG. 6 can be flipped 180 degrees, and a grinding treatment can be performed on the application wafer 1101. Afterwards, the through hole O can be formed in the application wafer 1101.

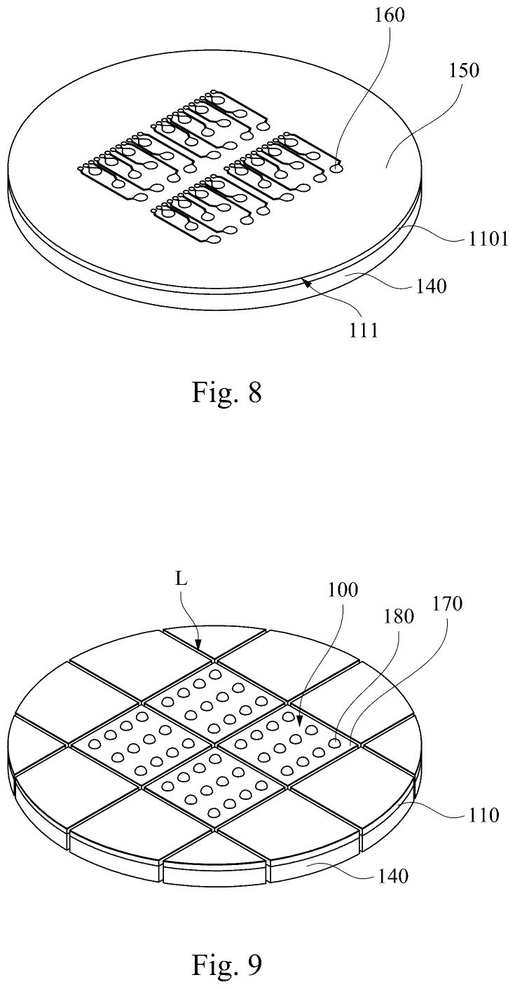

As shown in FIG. 8 and FIG. 9, after the formation of the through hole O, the isolation layer 150 may be formed on the surface 111 of the application wafer 1101 and the sidewall of the through hole O. Thereafter, the redistribution layer 160 can be formed such that the redistribution layer 160 is electrically connected to another conductive pad 112a (see FIG. 1) of the application wafer 1101 by the through hole O and extends to the surface 111 of the application wafer 1101. Subsequently, the passivation layer 170 can be formed to cover the isolation layer 150 and the redistribution layer 160, and then the passivation layer 170 is patterned to expose a portion of the redistribution layer 160. As a result, the conductive structure 180 may be formed on the exposed redistribution layer 160.

Thereafter, the passivation layer 170, the application wafer 1101, and the molding compound 140 can be cut to form the scribe line L and the application chip 110. Through the aforementioned steps, the chip package 100 of FIG. 1 can be obtained.

In the following description, other types of chip packages and manufacturing method thereof will be explained.

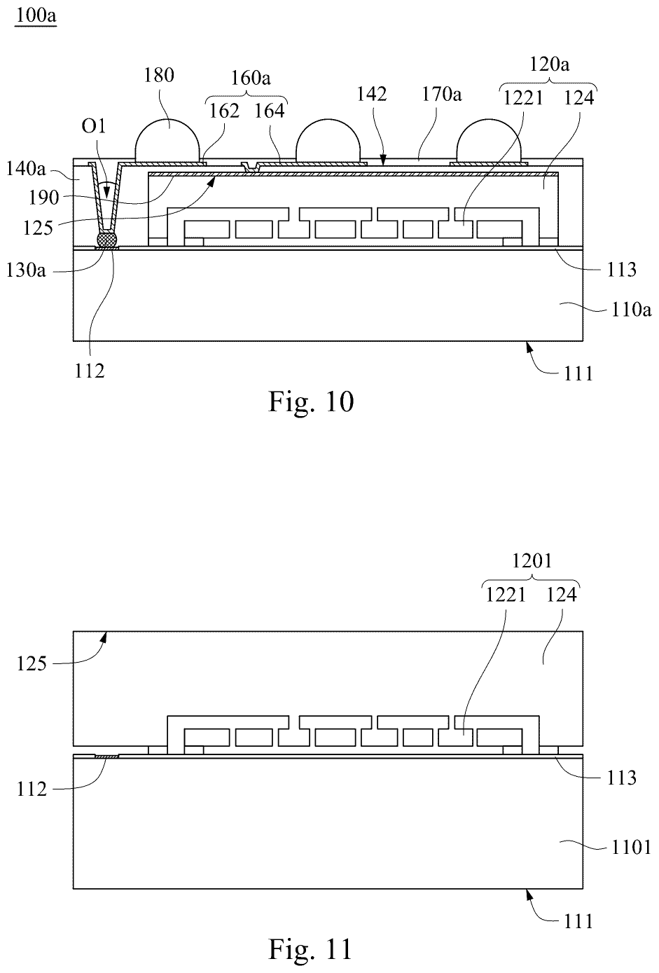

FIG. 10 is a cross-sectional view of a chip package 100a according to another embodiment of the present disclosure. As shown in FIG. 10, the chip package 100a includes an application chip 110a, a MEMS chip 120a, a first conductive element 130a, and a molding compound 140a. The application chip 110a has the conductive pad 112. The MEMS chip 120a is located on the application chip 110a, and includes a MEMS structure 1121 and the cap 124 that covers the MEMS structure 1121. The MEMS structure 1121 is located between the cap 124 and the application chip 110a. A surface 125 of the cap 124 facing away from the application chip 110a has a metal layer 190. The metal layer 190 can act as a metal shielding layer and a ground pad. The first conductive element 130a is located on the conductive pad 112 of the application chip 110a. The molding compound 140a is located on the application chip 110a, covers the metal layer 190, and surrounds the MEMS chip 120a. The first conductive element 130a is located in the molding compound 140a.

Specifically, since the chip package 100a has the first conductive element 130a in the molding compound 140a, the electrical connection between the application chip 110a and the conductive structure 180 on the molding compound 140a can be achieved. The chip package 100a can not only realize the integration of chips with different functions, but also effectively solve the problem of the grounding and shielding of micro-electromechanical systems, and can also achieve a balance between miniaturization design and structural strengthening.

In this embodiment, the application chip 110a may include the isolation layer 113, and the top surface of the conductive pad 112 is exposed by the isolation layer 113 for bonding the first conductive element 130a. The molding compound 140a has a through hole O1 aligned with the first conductive element 130a. The chip package 100a further includes a redistribution layer 160a, a passivation layer 170a, and two conductive structures 180. A first section 162 of the redistribution layer 160a is electrically connected to the first conductive element 130a in the through hole O1, and extends to the surface 142 of the molding compound 140a facing away from the MEMS chip 120a. A second section 164 of the redistribution layer 160a is electrically connected to the metal layer 190 and extends to the surface 142 of the molding compound 140a. The passivation layer 170a is located on the surface 142 of the molding compound 140a and covers the redistribution layer 160a. The two conductive structures 180 are respectively located on the first section 162 and the second section 164 of the redistribution layer 160a, and protrude from the passivation layer 170a. The conductive structures 180 can be electrically connected to an external device (e.g., a printed circuit board).

In the following description, the manufacturing method of the chip package 100a will be explained.

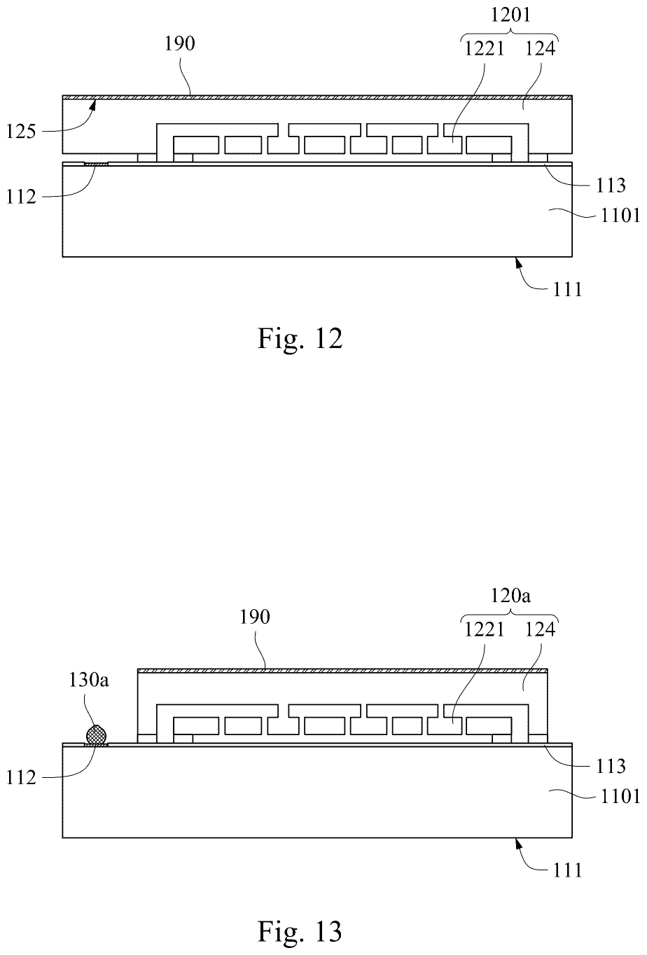

FIGS. 11 to 15 are cross-sectional views at intermediate stages of a manufacturing method of the chip package 100a of FIG. 10. As shown in FIG. 11 and FIG. 12, the MEMS wafer 1201 is bonded on the application wafer 1101, in which the MEMS wafer 1201 includes a MEMS structure 1221 and the cap 124 covering the MEMS structure 1221, and the MEMS structure 1221 is located between the cap 124 and the application wafer 1101. Thereafter, a grinding treatment can be performed on the surface 111 of the application wafer 1101 and the surface 125 of the MEMS wafer 1201 to thin the application wafer 1101 and the MEMS wafer 1201. For example, the application wafer 1101 and the MEMS wafer 1201 are thinned from 740 μm to 220 μm, but the present disclosure is not limited in this regard. Afterwards, the metal layer 190 may be formed on the surface 125 of the cap 124 facing away from the application wafer 1101.

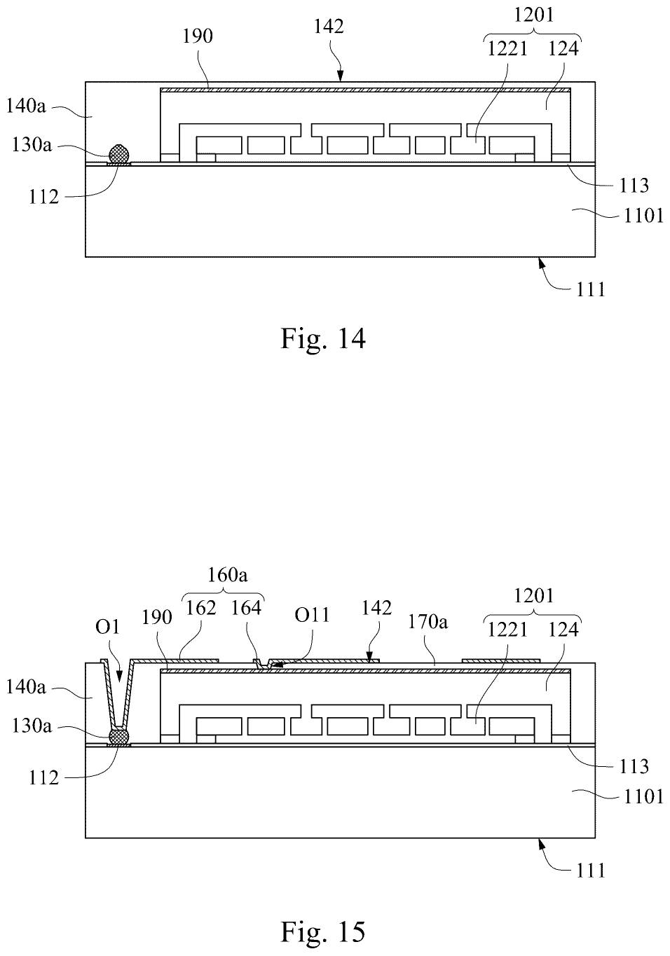

As shown in FIG. 13 and FIG. 14, after the formation of the metal layer 190, the MEMS wafer 1201 is cut to form at least one MEMS chip 120a such that the conductive pad 112 of the application wafer 1101 is exposed. Next, the first conductive element 130a can be bonded on the conductive pad 112 of the application wafer 1101. In the following step, the molding compound 140a can be formed on the application wafer 1101 to cover the metal layer 190 and surround the MEMS chip 120a. As a result, the first conductive element 130a is located in the molding compound 140a. In some embodiments, the molding compound 140a may be further thinned through grinding its surface 142.

As shown in FIG. 15 and FIG. 10, thereafter, the through hole O1 and an opening O11 are formed in the molding compound 140a by a laser, such that the first conductive element 130a is exposed through the through hole O1, and the metal layer 190 is exposed through the opening O11. Next, the redistribution layer 160a may be formed such that the first section 162 and the second section 164 of the redistribution layer 160a are electrically connected to the first conductive element 130a in the through hole O1 and the metal layer 190 in the opening O11, respectively, in which the first section 162 and the second section 164 of the redistribution layer 160a extend to the surface 142 of the molding compound 140a facing away from the MEMS chip 120a.

In the subsequent steps, the passivation layer 170a can be formed to cover the molding compound 140a and the redistribution layer 160a, and then the passivation layer 170a is patterned to expose the first section 162 and the second section 164 of the redistribution layer 160a. As a result, the two conductive structures 180 may be respectively formed on the exposed first and second sections 162 and 164 of the redistribution layer 160a. Thereafter, the passivation layer 170a, the molding compound 140a, and the application wafer 1101 can be cut to form the application chip 110a. Through the aforementioned steps, the chip package 100a of FIG. 10 can be obtained.

In the following description, other types of chip packages and manufacturing method thereof will be explained.

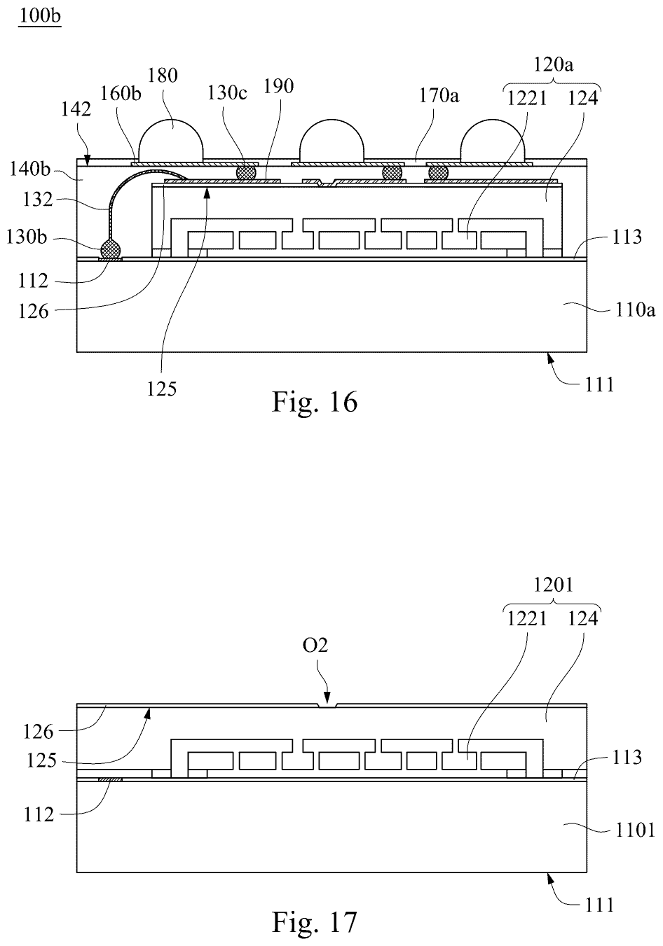

FIG. 16 is a cross-sectional view of a chip package 100b according to still another embodiment of the present disclosure. The chip package 100b includes the application chip 110a, the MEMS chip 120a, a first conductive element 130b, and a molding compound 140b. The difference between this embodiment and the embodiment of FIG. 10 is that the surface 125 of the cap 124 of the MEMS chip 120a has an isolation layer 126, and the chip package 100b further includes the bonding wire 132 and a second conductive element 130c. The isolation layer 126 is located between the metal layer 190 and the surface 125 of the cap 124. The metal layer 190 includes plural sections. The bonding wire 132 extends from the first conductive element 130b to one section of the metal layer 190, while another section of the metal layer 190 can be in electrical contact with the cap 124 of the MEMS chip 120a. The metal layer 190 may act as a metal shielding layer and a ground pad. In this embodiment, the second conductive element 130c is located on the metal layer 190, and is located in the molding compound 140b.

Moreover, a redistribution layer 160b of the chip package 100b is located on the surface 142 of the molding compound 140b facing away from the MEMS chip 120a, and is electrically connected to the second conductive element 130c. In addition, the conductive structure 180 is located on the redistribution layer 160b.

Specifically, since the chip package 100b has the first conductive element 130b in the molding compound 140b, the electrical connections between the application chip 110a and the MEMS chip 120a and between the application chip 110a and the conductive structure 180 on the molding compound 140b can be achieved. The chip package 100b can not only realize the integration of chips with different functions, but also effectively solve the problem of electrical connections between different chips and the problem of the grounding and shielding of micro-electromechanical systems. Furthermore, the chip package 100b can also achieve a balance between miniaturization design and structural strengthening.

FIGS. 17 to 21 are cross-sectional views at intermediate stages of a manufacturing method of the chip package 100b of FIG. 16. The steps for forming the chip package 100b before the step of FIG. 17 are similar to the steps before forming the metal layer 190 of FIG. 12, and will not be repeated. As shown in FIG. 17, after grinding the surface 111 of the application wafer 1101 and the surface 125 of the MEMS wafer 1201, the isolation layer 126 is formed on the surface 125 of the cap 124. The isolation layer 126 may be patterned to form an opening O2 that exposes the surface 125.

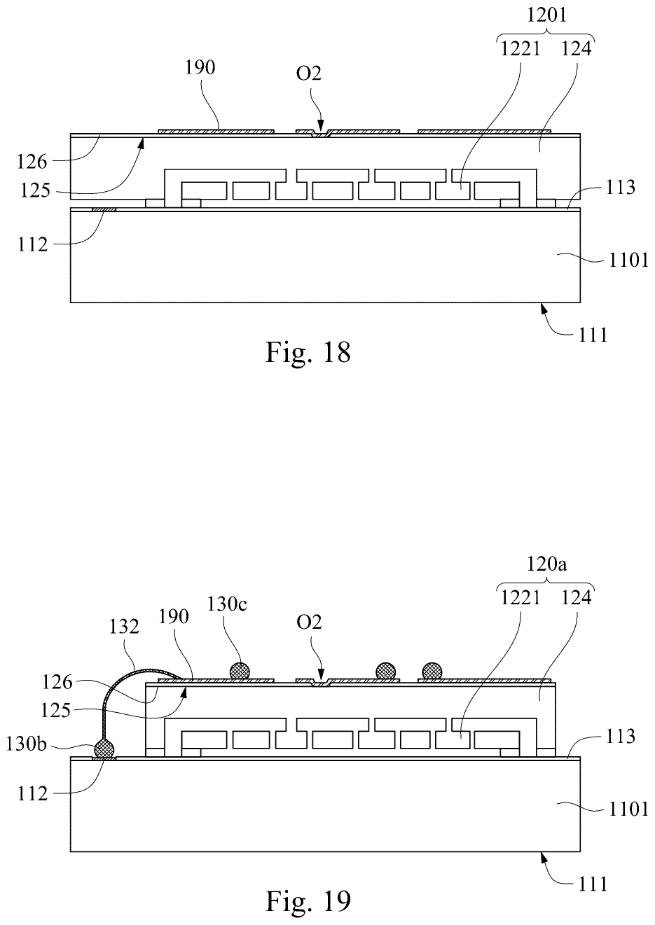

As shown in FIG. 18 and FIG. 19, after the formation of the isolation layer 126, the metal layer 190 can be formed on the isolation layer 126 on the surface 125 of the cap 124, and one section of the metal layer 190 may be in electrical contact with the cap 124. The material of the metal layer 190 may be, but not limited to aluminum. Thereafter, the MEMS wafer 1201 can be cut to form at least one MEMS chip 120a, such that the conductive pad 112 of the application wafer 1101 is exposed. Afterwards, the first conductive element 130b may be bonded on the conductive pad 112 of the application wafer 1101, and the bonding wire 132 extending form the first conductive element 130b to the metal layer 190 is formed. In this embodiment, the second conductive element 130c is further bonded on the metal layer 190.

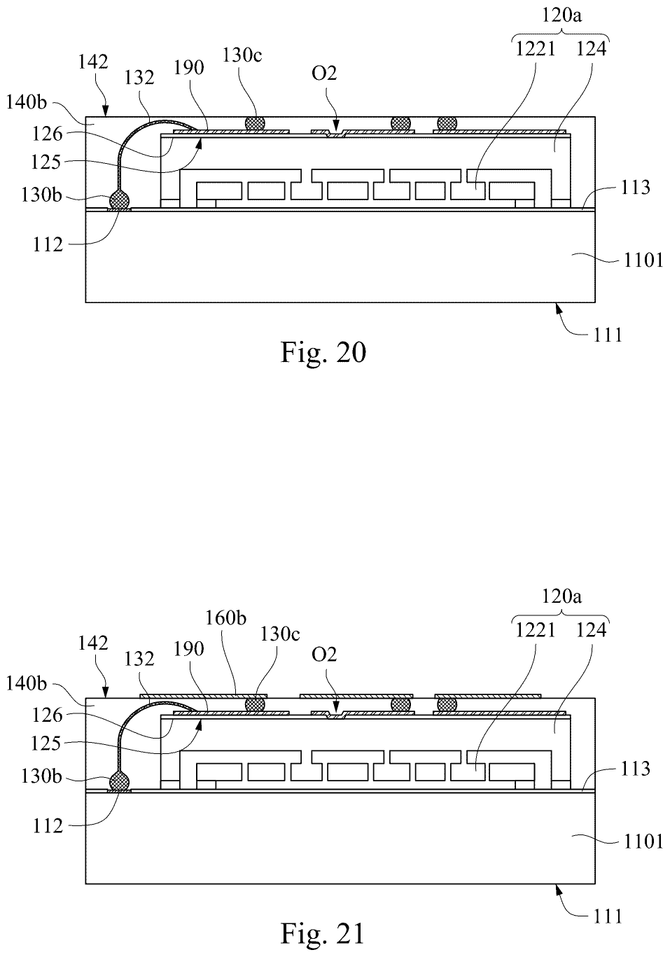

As shown in FIG. 20 and FIG. 21, thereafter, the molding compound 140b may be formed on the application wafer 1101 to cover the metal layer 190 and to surround the MEMS chip 120a. As a result, the first conductive element 130b and the second conductive element 130c are located in the molding compound 140b. In this embodiment, the molding compound 140b is thinned by grinding its surface 142 such that the second conductive element 130c is exposed. Next, the redistribution layer 160b may be formed on the surface 142 of the molding compound 140b facing away from the MEMS chip 120a, such that the redistribution layer 160b is electrically connected to the second conductive element 130c. The material of the redistribution layer 160b is different from the material of the metal layer 190. For example, the material of the redistribution layer 160b may be, but not limited to copper.

As shown in FIG. 21 and FIG. 16, in the subsequent steps, the passivation layer 170a can be formed to cover the molding compound 140b and the redistribution layer 160b, and then the passivation layer 170a is patterned to expose the redistribution layer 160b. As a result, the conductive structure 180 may be formed on the exposed the redistribution layer 160b. Thereafter, the passivation layer 170b, the molding compound 140b, and the application wafer 1101 can be cut to form the application chip 110a. Through the aforementioned steps, the chip package 100b of FIG. 16 can be obtained.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip package, comprising:
an application chip having a conductive pad;
a micro-electromechanical systems (MEMS) chip located on the application chip, and comprising a main body and a cap, wherein the main body is located between the cap and the application chip, and the main body has a conductive pad;
a conductive element located on the conductive pad of the main body of the MEMS chip;
a bonding wire extending from the conductive element to the conductive pad of the application chip; and
a molding compound located on the application chip and surrounding the MEMS chip, wherein the conductive element and the bonding wire are located in the molding compound.

2. The chip package of claim 1, wherein the molding compound is in direct contact with the conductive element and the bonding wire.

3. The chip package of claim 1, wherein a top surface of the molding compound is higher than the highest position of the bonding wire.

4. The chip package of claim 1, wherein the application chip has a through hole, and the chip package further comprises:
a redistribution layer electrically connected to another conductive pad of the application chip by the through hole, and extending to a surface of the application chip facing away from the MEMS chip; and
a conductive structure located on the redistribution layer.

5. A manufacturing method of a chip package, comprising:
cutting a cap of a micro-electromechanical systems (MEMS) wafer to form a plurality of scribe lines;
cutting a main body of the MEMS wafer along the scribe lines to form at least one MEMS chip, wherein the MEMS chip comprises the cap and the main body that are diced;
disposing the MEMS chip on an application wafer;
bonding a conductive element on a conductive pad of the main body of the MEMS chip;
extending a bonding wire from the conductive element to a conductive pad of the application wafer; and
forming a molding compound on the application wafer to enable the molding compound surrounding the MEMS chip, wherein the conductive element and the bonding wire are located in the molding compound.

6. The manufacturing method of the chip package of claim 5, further comprising:
forming a through hole in the application wafer;
forming a redistribution layer that is electrically connected to another conductive pad of the application wafer by the through hole, and extends to a surface of the application wafer facing away from the MEMS chip; and
forming a conductive structure on the redistribution layer.

7. A chip package, comprising:
an application chip having a conductive pad;
a micro-electromechanical systems (MEMS) chip located on the application chip, and comprising a MEMS structure and a cap covering the MEMS structure, wherein the MEMS structure is located between the cap and the application chip, and a surface of the cap facing away from the application chip has a metal layer;
a first conductive element located on the conductive pad of the application chip; and
a molding compound located on the application chip, covering the metal layer, and surrounding the MEMS chip, wherein the first conductive element is located in the molding compound.

8. The chip package of claim 7, wherein the molding compound has a through hole aligned with the first conductive element, and the chip package further comprises:
a redistribution layer, wherein a first section of the redistribution layer is electrically connected to the first conductive element in the molding compound, and extends to a surface of the molding compound facing away from the MEMS chip.

9. The chip package of claim 8, wherein a second section of the redistribution layer is electrically connected to the metal layer and extends to said surface of the molding compound.

10. The chip package of claim 9, further comprising:
a conductive structure located on the second section of the redistribution layer.

11. The chip package of claim 8, further comprising:
a conductive structure located on the first section of the redistribution layer.

12. The chip package of claim 7, wherein said surface of the cap has an isolation layer between the metal layer and said surface of the cap.

13. The chip package of claim 7, further comprising:
a bonding wire extending from the first conductive element to the metal layer.

14. The chip package of claim 7, further comprising:
a second conductive element located on the metal layer and in the molding compound.

15. The chip package of claim 14, further comprising:
a redistribution layer located on a surface of the molding compound facing away from the MEMS chip, and electrically connected to the second conductive element.

16. The chip package of claim 15, further comprising:
a conductive structure located on the redistribution layer.

17. A manufacturing method of a chip package, comprising:
bonding a micro-electromechanical systems (MEMS) wafer on an application wafer, wherein the MEMS wafer comprises a MEMS structure and a cap covering the MEMS structure, wherein the MEMS structure is located between the cap and the application wafer;
forming a metal layer on a surface of the cap facing away from the application wafer;
cutting the MEMS wafer to form at least one MEMS chip such that a conductive pad of the application wafer is exposed;
bonding a first conductive element on the conductive pad of the application wafer; and
forming a molding compound on the application wafer to cover the metal layer and surround the MEMS chip, wherein the first conductive element is located in the molding compound.

18. The manufacturing method of the chip package of claim 17, further comprising:
forming a through hole and an opening in the molding compound by a laser, such that the first conductive element is exposed through the through hole, and the metal layer is exposed through the opening; and
forming a redistribution layer such that a first section and a second section of the redistribution layer are electrically connected to the first conductive element in the through hole and the metal layer in the opening, respectively, wherein the first section and the second section of the redistribution layer extend to a surface of the molding compound facing away from the MEMS chip.

19. The manufacturing method of the chip package of claim 17, further comprising:
before forming the metal layer, forming an isolation layer on said surface of the cap.

20. The manufacturing method of the chip package of claim 17, further comprising:
bonding a second conductive element on the metal layer, such that the second conductive element is located in the molding compound after forming the molding compound;
forming a bonding wire that extends from the first conductive element to the metal layer; and
forming a redistribution layer on a surface of the molding compound facing away from the MEMS chip, such that the redistribution layer is electrically connected to the second conductive element.
